(19) United States
(12) Patent Application Publication
(10) Pub. No.: US 2018/0368293 A1
(43) Pub. Date: Dec. 20, 2018

(54) Stable Power Capacitors by Thermoelectric Cooling

(71) Applicant: KEMET Electronics Corporation, Simpsonville, SC (US)

(72) Inventors: JOHN BULTITUDE, Simpsonville, SC (US); John McConnell, Simpsonville, SC (US)

(73) Assignee: KEMET Electronics Corporation

(21) Appl. No.: 15/972,988

(22) Filed: May 7, 2018

Related U.S. Application Data
(63) Continuation of application No. 62/522,297, filed on Jun. 20, 2017.

(51) Int. Cl. H05K 7/20; H01G 4/258; H01G 9/14

(52) U.S. Cl. CPC H05K 7/20945; H01G 9/14; H01G 4/258; H05K 7/20918

(57) ABSTRACT

Provided is an electronic module comprising at least one electronic component. A thermoelectric cooler is in thermal contact with the electronic component. A temperature controller is capable of determining a device temperature of the electronic component is provided and capable of providing current to the thermoelectric cooler proportional to a deviation of the device temperature from an optimal temperature range.

### CROSS-REFERENCE TO RELATED APPLICATIONS

The present application claims priority to pending U.S. Provisional Patent Application No. 62/522,297 filed Jun. 20, 2017 which is incorporated herein by reference.

### BACKGROUND

The present invention is related to an improved electronic module, comprising at least one temperature sensitive capacitor, such as an electrolytic, film, or a multi-layered ceramic (MLCC) capacitor. More specifically, the present invention is related to an electronic module comprising a temperature sensitive capacitor which is thermally stabilized by an integral thermoelectric cooler.

The demand for increased functionality of electronic products continues to expand as new technologies with greater capabilities are developed. The continued expansion of electronics in applications, once considered unsuitable, are now becoming the norm. These new applications demand high operating and processing speeds, increased electrical performance in a smaller space, and harsh environment applications such as high temperature and humidity. In electronics, increased performance is based on higher power conversion which also increases the operating temperature of the component. In the case of ceramic capacitors having specific types of dielectrics, the capacitance of a capacitor changes as the temperature of the component increases adversely affecting the performance of the capacitor. For film capacitors, the maximum operating temperature may be limited by the intrinsic stability of the film material. In electrolytic capacitors, the counterelectrode materials or the electrolyte often limit the maximum use temperature. In many cases, the temperature increase is significant enough to justify the use of heat sinks to help dissipate the increase in heat to help keep the component operating within an optimal temperature range.

The dissipation of heat from a source is an age-old endeavor. The efficiency of heat sinking has improved over the years because of improved designs, materials, and technology. Some heat sinks may be as simple as utilizing a mass of material having good thermal dissipation properties, such as copper or aluminum, and mounting a heat generating device onto the material. The addition of fins to the heat sink to increase surface area or cavities within the heat sink to circulate a cooling fluid, such as water, can also be used to increase the heat sinking capabilities. Other materials, such as AlN or BeO ceramics, are also utilized as heat sinks due to their excellent heat sinking capabilities. The amount of thermal dissipation varies with the different types of heat sinks and trying to control the dissipation may become more complicated as the degree of accuracy becomes more critical.

While heat sink technology is beneficial the use thereof is in conflict with the ongoing desire for miniaturization. As more demand is placed on electronic assemblies, and therefore electronic components, the decreasing space available for a heat sink diminishes as does the area available for circulation of a transfer medium, such as air, within the device. Furthermore, heat sinks are passive devices incapable of intermittent function and they are inadequate for use in low temperature environments wherein the temperature of the component may need to be heated to achieve adequate functionality.

There is an ongoing desire in the art for a more robust electronic module, and particularly an electronic module comprising a capacitor that has an optimal range of temperature where its capacitance remains stable. In resonator circuits containing capacitors, it is critical to maintain the capacitance within narrow limits. Since capacitance varies with temperature common heat sinks alone are not capable of achieving the temperature stability that is required. These modules are also required to have reliable performance over a wide temperature range and to eliminate failures due to thermal runaway.

### SUMMARY OF THE INVENTION

The present invention is related to an improved electronic module and particularly an improved electronic module comprising an electrolytic, film, or multi-layered ceramic capacitor (MLCC) and a thermoelectric cooler (TEC) in thermal contact therewith.

More specifically, the present invention is related to an improved electronic module comprising a capacitor having stable power due to the incorporation of an integral thermoelectric cooler in thermal contact therewith.

A particular feature of the invention is the ability to maintain an electrolytic, film, or MLCC capacitor of an electronic module within a temperature range thereby improving the performance of the capacitor and electronic module.

A particular advantage is the ability to provide an electronic module comprising a capacitor with an integral safety device thereby avoiding thermal runaway.

These and other embodiments, as will be realized, are provided in an electronic module comprising at least one electronic component. A thermoelectric cooler is in thermal contact with the electronic component. A temperature controller is capable of determining a device temperature of the electronic component is provided and capable of providing current to the thermoelectric cooler proportional to a deviation of the device temperature from an optimal temperature range.

Yet another embodiment of the invention is provided in a method for controlling a device temperature of a capacitor comprising:

forming an electronic module comprising at least one capacitor wherein the capacitor comprises an optimal temperature range;
placing a thermoelectric cooler in thermal contact with the capacitor; and providing a thermal controller comprising a temperature sensor capable of measuring the device temperature of the capacitor and providing a current to the thermoelectric cooler wherein the current is proportional to a deviation of the device temperature from the optimal temperature range.

### BRIEF DESCRIPTION OF DRAWINGS

FIG. 1 is a schematic perspective view of an embodiment of the invention.

FIG. 2 is a schematic perspective view of an embodiment of the invention.

FIG. 3 is an electrical schematic diagram of a fixture for demonstration of the invention.

FIG. 4 is a schematic perspective view of an embodiment of the invention.

FIG. 5 is a schematic perspective view of an embodiment of the invention.

FIG. 6 is a schematic representation of an embodiment of the invention.

FIG. 7 is a partially expanded perspective schematic view of an embodiment of the invention.

FIG. 8 is a schematic representation of a series resonate circuit with controls.

FIG. 9 is a schematic representation of a parallel resonate circuit.

### DESCRIPTION

The present invention is related to an improved electronic module preferably comprising a capacitor which is thermally stabilized by an integral thermoelectric cooler. In particular the present invention is related to an improved electronic module comprising a multilayered ceramic capacitor (MLCC), electrolytic capacitor or film capacitor which is thermally stabilized by an integral thermoelectric cooler More specifically, the present invention allows an MLCC, electrolytic, or film capacitor or an electronic module to be maintained within a predetermined temperature range thereby improving the functionality of the capacitor and module comprising the capacitor.

A thermoelectric cooler (TEC) is a solid-state device, based on an application of Peltier Effect, which functions as a solid-state heating or cooling generator based on semi-conductor technology. When current is passed through a TEC one side becomes hot while the other side becomes cold and when the current flow is reversed the hot and cold sides flip positions thus creating a solid-state heater or cooler having no moving parts. When multiple blocks of this material are connected in series circuit, the heat generation or cooling effect can be increased by stacking the TEC with the hot side of one TEC in contact with the cold side of a second TEC.

The application described herein provides an electronic module utilizing TEC's with temperature feedback to one or multiple electronic components, preferably MLCC's, that will maintain an optimum operating temperature range. The electronic component and TEC are in thermal contact defined herein as a relationship wherein the TEC can heat or cool the capacitor in response to a current applied to the TEC. When the capacitor element is being used in a resonator circuit it is particularly essential to maintain a tight control of capacitance which in many capacitors requires a narrow range of temperature to be maintained. The TEC allows the capacitor temperature to be controlled within a narrow range by either heating or cooling.

Certain dielectrics used in MLCC's have specific dielectric properties that provide optimal capacitance properties for an MLCC. However, some dielectrics are sensitive to heat and a decrease in their capacitance can occur as the temperature of the MLCC increases. In these instances, it becomes desirable to maintain an optimum component temperature thereby allowing the component to operate at its maximum capacitance capability. This is particularly an issue with MLCC's wherein the capacitance is temperature sensitive. Temperature control can be achieved by mounting the electronic component to the TEC and utilizing surface mounted circuitry as described in U.S. Pat. No. 8,904,609, which is incorporated herein by reference, to incorporate a temperature sensing closed loop control circuit within the envelope of the electronic component.

The temperature can be determined by a predictive method, a direct method or a combination thereof. A predictive method would include a determination of temperature based on the measurement of a secondary parameter wherein the secondary parameter correlates to temperature such as current, resistance or capacitance. A direct method is a measurement of temperature by a temperature sensor which can be a contact sensor or a remote sensor. Sensors which can be employed for demonstration of the invention include a varistor, resistive temperature detector, thermistor, infrared detector, bi-metallic sensor, silicon diode, semiconductor with temperature sensitive voltage vs. current, thermocouple, optical sensor or any other temperature sensing device capable of sensing the temperature of the electronic component. It is preferable that the temperature sensor be an integral part of the temperature control circuit wherein the temperature control circuit varies the current flow to the TEC, thus, heating or cooling the electronic component to maintain an operating temperature within a preferred operating temperature range. The application of utilizing the TEC as a temperature controller can be utilized for many capacitor assembly designs and may include additional components.

In a particularly preferred embodiment a combination of predictive and direct temperature sensors can be employed. Based on parameters monitored by predictive temperature sensor the TEC may be activated before a threshold temperature is achieved and the current to the TEC may be proportional to the temperature difference relative to a predetermined temperature or temperature range thereby allowing for proportional temperature correction. The direct temperature sensor could provide redundancy or confirmation of the temperature of the electronic component.

Alternatively, the direct temperature sensor may be monitored for determination of a threshold temperature above which a predictive sensor is monitored for effectiveness of temperature alteration by the TEC.

The invention will be described with reference to the figures forming an integral component of the instant disclosure without limit thereto. Throughout the various figures similar elements will be numbered accordingly.

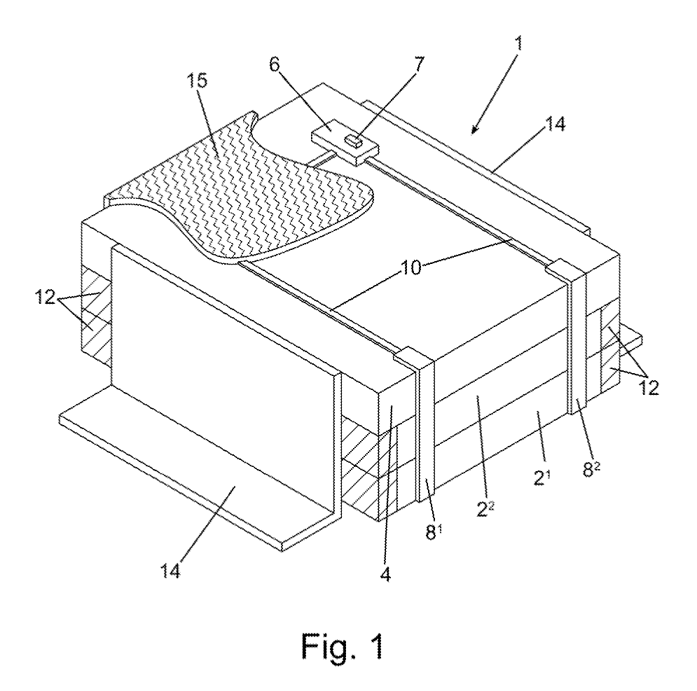

An embodiment of the invention is illustrated in schematic perspective view in FIG. 1. In FIG. 1 an electronic module, generally represented at 1, comprises a stack of components, 2, with a preference for at least one component being an MLCC. A stack of two components is illustrated for the purposes of discussion without limit thereto. Each component has external terminations, 12, with each component having external terminations of different polarity. Adjacent external terminations of adjacent components are optionally electrically attached to leads, 14, for mounting to circuit traces of a circuit board. A TEC, 4, in thermal contact with at least one component is commonly stacked with the components. An integral temperature controller module, 6, monitors the temperature of the components and relays a current to the TEC through traces, 10, such as on the surface, to conductive leads, 8, which are in electrical communication with the TEC. The module comprises a temperature sensor, 7, which is either integral to or in electronic communication with the temperature sensor module. The power to the TEC can be increased or decreased to maintain a constant operating temperature of the electronic component with the power being proportional to the temperature change of the TEC. By changing the polarity of the input to the TEC it can be made to heat or cool. At least a portion of the electronic component is optionally encased in an overmolding material, 15, wherein the overmolding is illustrated in partial cut-away.

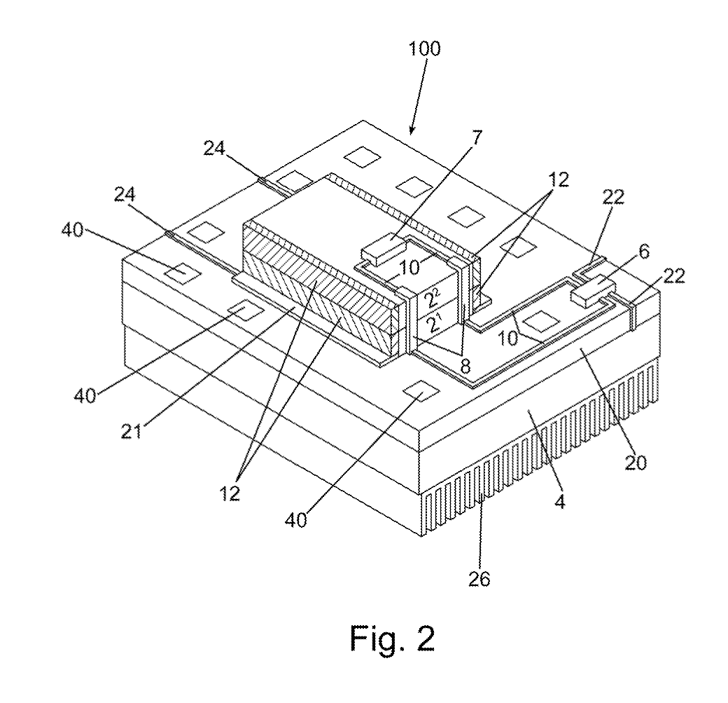

An embodiment of the invention will be illustrated with reference to FIG. 2 wherein an electronic module is generally represented in perspective schematic view at 100. In FIG. 2, a stack of components, 2, at least one of which is preferably an MLCC is mounted to a circuit board, 20, wherein the circuit board comprises capacitive traces, 24, in electrical connectivity with the external terminations, 12, of the components, 2, preferably through conductive pads, 21. A temperature sensor, 7, is in thermal contact with at least one electronic component and capable of relaying a signal to the temperature controller module, 6, preferably mounted on the circuit board, 20, through traces, 10, and conductive leads, 8, wherein the conductive lead may be a continuing portion of the trace. The controller module provides current to the TEC, 4, with a polarity sufficient to heat the surface upon which the capacitor is mounted or cool the surface upon which the capacitor is mounted through TEC traces, 22. Additional power traces for the control module are not shown but would be understood to be integral to the control module functionality. An optional heat sink, 26, can be employed to remove heat from the surface of the TEC. It is preferable that the heat sink and electronic component be in thermal contact with opposite sides of the TEC thereby allowing heat generated by the TEC to be dissipated through the heat sink. Integral heat spreaders, 40, facilitate thermal transfer through the substrate. Heat spreaders are thermally conductive materials which extend along, through or around the circuit board to provide a thermal conduit for transfer to heat to or from the TEC to the capacitor. Alternatively, the circuit board may be a thermal conductor.

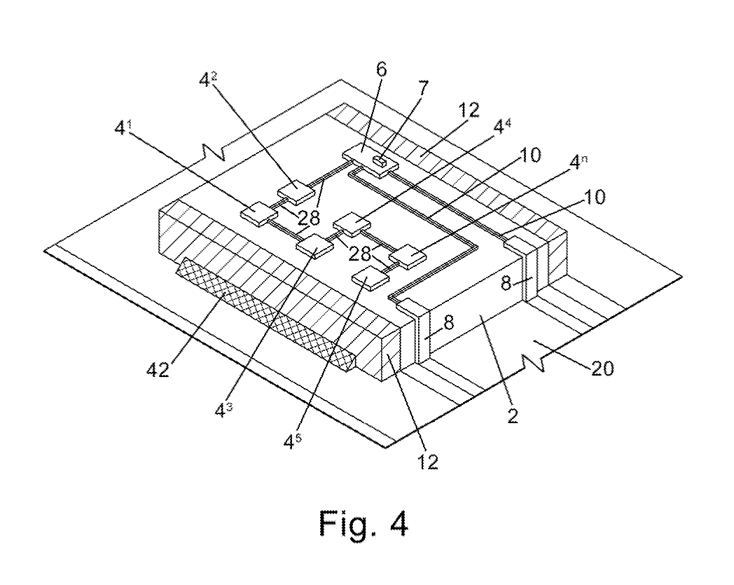

An embodiment of the invention is illustrated in perspective schematic view in FIG. 4. In FIG. 4, an MLCC, 2, is illustrated mounted directly to a circuit board, 20, by a conductive adhesive, 42. A multiplicity of TEC's, 4, are on the surface of the MLCC with each TEC in electrical contact with a temperature controller module, 6, and integral temperature sensor, 7, by communication traces, 28, which allow the TEC's to be energized collectively, individually or in select groups thereby allowing for fine control of the temperature.

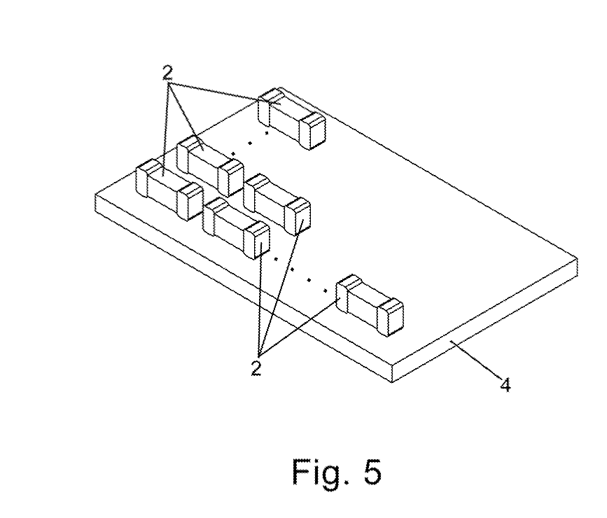

An embodiment of the invention is illustrated in schematic view in FIG. 5 wherein a series of MLCCs, 2, are on a common TEC, 4. The temperature control module is not shown. Temperature can be determined at a single MLCC, all MLCC's or select groups of MLCC's with the TEC energized appropriately.

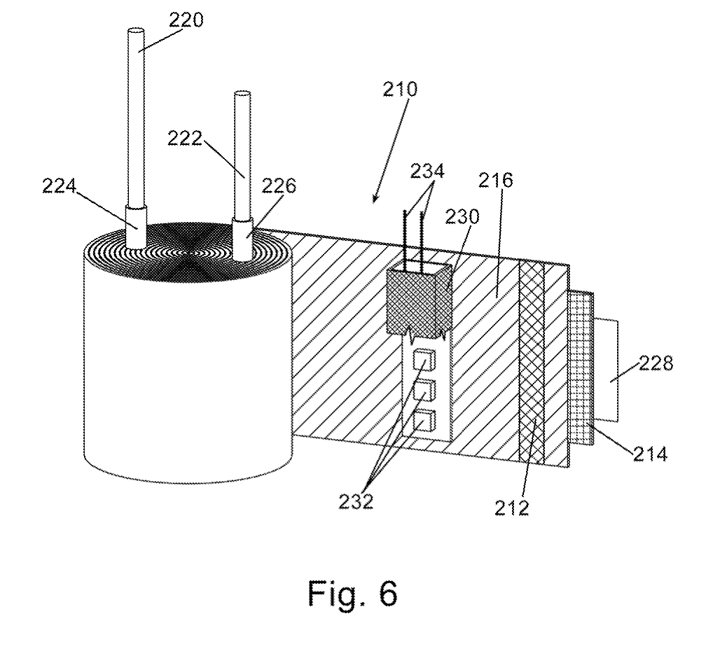

An electrolytic capacitor is illustrated in schematic perspective view in FIG. 6. In FIG. 6, a working element, such as aluminum, is shown in schematic partially unwound view prior to insertion into a container and impregnation with liquid electrolyte. In FIG. 6, the working element, generally represented at 210, comprises an anode, 212, and a cathode, 214, with a separator, 216, there between. An anode lead, 220, and cathode lead, 222, extend from the wound capacitor and ultimately form the electrical connectivity to a circuit. It would be understood from the description that the anode lead is in electrical contact with the anode and the cathode lead is in electrical contact with the cathode and electrically isolated from the anode or anode lead. Tabs, 224 and 226, are commonly employed to electrically connect the anode lead to the anode and the cathode lead to the cathode as known in the art. A closure, 228, such as an adhesive tape inhibits the working element from unwinding during handling and assembly after which the closure has little duty even though it is part of the finished capacitor. A channel, 230, preferably of a thermally conducting material is incorporated in the winding wherein at least one TEC, 232, is within the channel and in thermal communication with the electrolytic capacitor. The channel may be at any location within the electrolytic capacitor and multiple channels may be used if necessary to provide sufficient temperature control. Power leads, 234, extend from the channel to provide power to a temperature controller module (now shown) and associated temperature sensor (not shown) and to the TEC. The thermal controller module may be exterior to the electrolytic capacitor. In one embodiment the channel allows for medium, such as air or a liquid, to flow therethrough thereby allowing for heat dissipation. Alternatively, the liquid electrolyte can flow through the channel wherein the liquid electrolyte exchanges heat through the metal case. While illustrated in FIG. 6 with an electrolytic capacitor, one of skill in the art would understand from the drawings and description that the layers can be replaced with a film capacitor with the channel, and at least one TEC, in thermal contact with at least one layer of a film capacitor to provide temperature control therein.

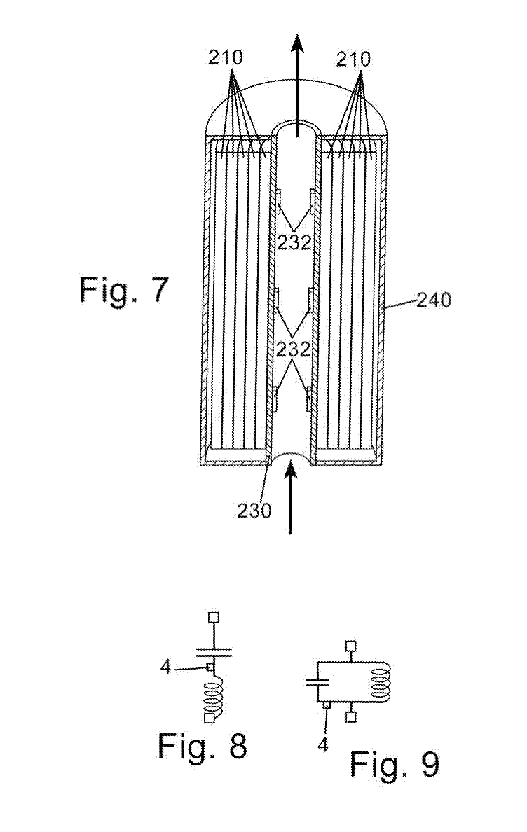

An embodiment of the invention is illustrated in cross-sectional schematic view in FIG. 7. In FIG. 7, the working element, 210, and electrolyte are sealed within a case, 240, as known in the art. A channel, 230, functions as a mandrel wherein at least one TEC, 232, is in thermal communication with the channel. In one embodiment the channel vents to the exterior as illustrated, however, in another embodiment the liquid electrolyte flows through the channel thereby allowing thermal transfer through the liquid electrolyte and case. The channel is preferably not a thermal insulator.

The shape of the channel is not limited with the proviso that it is preferable to maximize the contact area between the TEC and channel and therefore flattened portions are preferred.

An embodiment of the invention is illustrated in an electrical schematic view in FIGS. 8 and 9 wherein illustrated are a series and parallel LC resonator, respectively. LC resonators are particularly vulnerable to temperature variations and therefore an integral TEC, 4, would be advantageous.

In operation, if the temperature sensor senses a temperature of the component which is outside a predetermined optimal temperature range an appropriate signal is relayed to the temperature control circuit and the appropriate current is applied to the TEC thereby returning the component to a temperature within the predetermined range. As would be realized the temperature of the component can be raised or lowered with a preference for lowering the temperature particularly when the component is a capacitor.

Thermoelectric materials are typically fabricated from bismuth telluride (Bi₂Te₃), antimony telluride (Sb₂Te₃), lead telluride (PbTe) or alloys thereof such as Bi_{0.5}Sb_{1.5}Te₃ which is typically capable of achieving temperature change of about 81 K at a near ambient temperature of 300 K.

TEC's are commercially available in a variety of sizes and configurations from various companies including Marlow Industries, Inc. of Dallas, Tex. The TEC is preferably mounted to either the electronic component or circuit board by thermal epoxy, soldering, TLPS or by compression methods using thermal grease. It is preferably to control the TEC using linear proportional temperature control.

The circuit board preferably comprises a material selected from the group consisting of ceramic such as alumina such as 96% Al₂O₃ or 99.6% Al₂O₃; aluminum nitride; silicon nitride or beryllium oxide; G10; FR (Flame Retardant) materials such as FR 1-6, FR 4 which is a composite of epoxy and glass, FR2 utilizing phenolic paper or phenolic cotton and paper; Composite Epoxy Materials (CEM) such as CEM 1, 2, 3, 4, 5; insulated metal substrates such as aluminum substrates available from Berquist Mfg. and flex circuits comprising materials such as polyimide.

### EXAMPLES

### Example 1

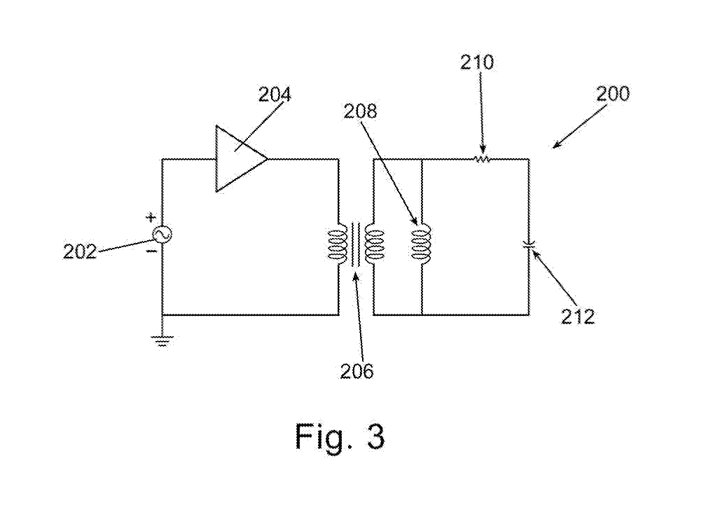

A test fixture was prepared comprising a TEC mounted to a Low R-theta, such as less than 1° C./watt, heat sink on one side and on the other side a stack of commercially available 3640 C0G capacitors available from KEMET having a capacitance of 0.056 μF, a rated voltage of 1000 volts and a nominal size of 9.1 mm×10.2 mm×2.7 mm. A 50.8 mm×25.4 mm FR4 substrate with copper pads was mounted to the capacitor stack opposite the TEC. A power amplifier having a circuit as illustrated schematically in FIG. 3, generally represented at 200, was configured for testing the ripple current. In FIG. 3, the power amplifier comprises a sine generator, 202, a power amplifier, 204, a toroidal transformer, 206, an inductor, 208, a resistor, 210, and the capacitor, 212, the device under test, which may be a single capacitor or a stack of capacitors.

The effects of the TEC on the temperature of ten MLCC's mounted in series is provide in Table 1 measured at a frequency of 563 kHz and an ESR of 1 mΩ wherein at a given AC RMS current (I), dissipated power (DP) in watts, the termination temperature without the TEC energized (Temp 1) the TEC voltage (TEC-V), and TEC current (TEC-I) required to achieve the stated cooled temperature (Temp 2) and the TEC Power (TEC-P) in watts is provided.

TABLE 1

| I | Temp 1 | DP | TEC-V | TEC-I | Temp 2 | TEC-P |
|---|---|---|---|---|---|---|
| (A RMS) | (° C.) | (W RMS) | (Vdc) | (A dc) | (° C.) | (W dc) |
| 0 | 24 | 0 | — | — | — | — |
| 10 | 29 | 0.1 | 0.6 | 0.22 | 24 | 0.132 |
| 15 | 35 | 0.225 | 1.2 | 0.44 | 25 | 0.528 |

As evidenced in Table 1, as the temperature of the MLCC's increases the dissipated power increases as the temperature can be lowered by the use of a TEC in thermal contact with the MLCC.

### Example 2

The test fixture of Example 1 was loaded with a stack of two commercially available 2220 X7R MLCC capacitors available from KEMET having a capacitance of 0.47 μF, a rated voltage of 50 volts and a nominal size of 5.70 mm×5.00 mm×1.85 mm. The effects of the TEC on the performance of the two MLCC's mounted in series is provide in Table 2 measured at a frequency of 28 kHz and an ESR of 4 mΩ wherein at a given AC RMS current (I), dissipated power (DP) in watts, the termination temperature without the TEC energized (Temp 1) the TEC voltage (TEC-V), and TEC current (TEC-I) required to achieve the stated cooled temperature (Temp 2) are reported. Capacitance Change with Reference to +25° C. and 0 VDC Applied (TCC) as a function of temperature (° C.) for a single 2220 X7R MLCC capacitor is provided in Table 3

TABLE 2

| I | Temp 1 | DP | TEC-V | TEC-I | Temp 2 |
|---|---|---|---|---|---|
| (A RMS) | (° C.) | (W RMS) | (V dc) | (A dc) | (° C.) |
| 10 | 40 | 0.40 | 2 | 0.73 | 27 |
| 12 | 50 | 0.60 | 3.5 | 1.3 | 30 |

TABLE 3

| Temperature | TCC |
|---|---|
| (° C.) | (%) |
| −55 | −4.73 |
| −35 | −2.62 |
| −15 | −1.50 |
| 5 | −0.69 |
| 25 | 0.00 |
| 45 | 0.08 |
| 65 | −1.825 |
| 85 | −4.393 |
| 105 | −6.103 |
| 125 | −6.464 |
| 150 | −25.343 |

As evidenced in Table 3, the temperature coefficient of capacitance for this representative capacitor reaches a threshold temperature at about 125° C. resulting in a significant decrease in capacitance. By maintaining the temperature of the MLCC within a predetermined optimal temperature range which is the range between a low temperature where capacitance changes to an unacceptable amount to a high temperature which is below the temperature at which thermal run-away can occur. By maintaining the temperature within the optimum temperature range thermal run-away can be avoided thereby providing a safer electronic component and ultimately a safer electronic device.

The invention has been described with reference to the preferred embodiments without limit thereto. Additional embodiments and improvements may be realized which are not specifically set forth herein but which are within the scope of the invention as more specifically set forth in the claims appended hereto.

1. An electronic module comprising:
at least one electronic component;
a thermoelectric cooler in thermal contact with said electronic component;
a temperature controller capable of determining a device temperature of said electronic component and capable of providing current to said thermoelectric cooler proportional to a deviation of said device temperature from an optimal temperature range.

2. The electronic module of claim 1 wherein at least one said electronic component is a capacitor.

3. The electronic module of claim 2 wherein said capacitor is a multilayered ceramic capacitor.

4. The electronic module of claim 2 wherein said capacitor is an electrolytic capacitor.

5. The electronic module of claim 2 wherein said capacitor is a film capacitor.

6. The electronic module of claim 4 wherein said electrolytic capacitor comprises at least one channel with at least one said thermoelectric cooler in at least one said channel.

7. The electronic module of claim 6 wherein at least one said channel is a mandrel.

8. The electronic module of claim 1 comprising multiple electronic components in thermal contact with said thermoelectric cooler.

9. The electronic module of claim 1 comprising multiple thermoelectric coolers in thermal contact with said electronic component.

10. The electronic module of claim 1 comprising multiple electronic components.

11. The electronic module of claim 10 wherein each said electronic component of said electronic components is a multi-layered ceramic capacitor.

12. The electronic module of claim 1 wherein said temperature is determined by a method selected from direct and predictive.

13. The electronic module of claim 1 wherein said temperature controller comprises a temperature sensor selected from the group consisting of a varistor, a resistive temperature detector, a thermistor, an infrared detector, a bi-metallic sensor, a silicone diode, a semiconductor with temperature sensitive voltage vs. current, a thermocouple and an optical sensor.

14. The electronic module of claim 1 wherein said current provided to said thermoelectric cooler proportionally lowers said device temperature.

15. The electronic module of claim 1 wherein said current provided to said thermoelectric cooler proportionally raises said device temperature.

16. The electronic module of claim 1 further comprising a circuit board.

17. The electronic module of claim 16 wherein at least a portion of said temperature controller is mounted to said circuit board.

18. The electronic module of claim 16 wherein said circuit board comprises an inorganic material selected from the group consisting of a ceramic; G10; an FR material; a Composite Epoxy Material (CEM), insulated metal substrate, and flexible substrate.

19. The electronic module of claim 18 wherein said circuit board comprises a material selected from the group consisting of alumina; aluminum nitride; silicon nitride and beryllium oxide.

20. The electronic module of claim 18 wherein said material is selected from the group consisting of organic materials FR 1, FR 2, FR 3, FR 4, FR 5, FR 6, CEM 1, CEM 2, CEM 3, CEM 4, CEM 5 or polyimide.

21. The electronic module of claim 16 wherein said electronic component is between said circuit board and said thermoelectric cooler.

22. The electronic module of claim 16 wherein said thermoelectric cooler is between said circuit board and said electronic component.

23. The electronic module of claim 1 further comprising an overmolding over at least a portion of said electronic module.

24. The electronic module of claim 1 further comprising a heat sink in thermal contact with said thermoelectric cooler.

25. The electronic module of claim 24 wherein said heat sink is in thermal contact with said thermoelectric cooler opposite said electronic component.

26. A method for controlling a device temperature of a capacitor comprising:
forming an electronic module comprising at least one capacitor wherein said capacitor comprises an optimal temperature range;
placing a thermoelectric cooler in thermal contact with said capacitor; and
providing a thermal controller comprising a temperature sensor capable of measuring said device temperature of said capacitor and providing a current to said thermoelectric cooler wherein said current is proportional to a deviation of said device temperature from said optimal temperature range.

27. The method for controlling a device temperature of a capacitor of claim 26 wherein said capacitor is a multilayered ceramic capacitor.

28. The method for controlling a device temperature of a capacitor of claim 26 wherein said capacitor is an electrolytic capacitor.

29. The method for controlling a device temperature of a capacitor of claim 28 wherein said capacitor is a film capacitor.

30. The method for controlling a device temperature of a capacitor of claim 28 wherein said electrolytic capacitor comprises at least one channel with at least one said thermoelectric cooler in at least one said channel.

31. The method for controlling a device temperature of a capacitor of claim 29 wherein at least one said channel is a mandrel.

32. The method for controlling a device temperature of a capacitor of claim 26 comprising multiple electronic components in thermal contact with said thermoelectric cooler.

33. The method for controlling a device temperature of a capacitor of claim 26 comprising multiple thermoelectric coolers in thermal contact with said electronic component.

34. The method for controlling a device temperature of a capacitor of claim 26 wherein said electronic module comprises multiple multi-layered ceramic capacitors.

35. The method for controlling a device temperature of a capacitor of claim 26 wherein said temperature is determined by a method selected from direct and predictive.

36. The method for controlling a device temperature of a capacitor of claim 26 wherein said temperature controller comprises a temperature sensor selected from the group consisting of a varistor, a resistive temperature detector, a thermistor, an infrared detector, a bi-metallic sensor, a silicone diode, a semiconductor with temperature sensitive voltage vs. current, a thermocouple and an optical sensor.

37. The method for controlling a device temperature of a capacitor of claim 26 wherein said current provided to said thermoelectric cooler proportionally lowers said device temperature.

38. The method for controlling a device temperature of a capacitor of claim 26 wherein said current provided to said thermoelectric cooler proportionally raises said device temperature.

39. The method for controlling a device temperature of a capacitor of claim 26 wherein said electronic module further comprising a circuit board.

40. The method for controlling a device temperature of a capacitor of claim 39 wherein at least a portion of said temperature controller is mounted to said circuit board.

41. The method for controlling a device temperature of a capacitor of claim 40 wherein said thermoelectric cooler is between said multi-layered ceramic capacitor and said circuit board.

42. The method for controlling a device temperature of a capacitor of claim 39 wherein said circuit board comprises an inorganic material selected from the group consisting of a ceramic; G10; an FR material; a Composite Epoxy Material (CEM), insulated metal substrate and flexible circuits.

43. The method for controlling a device temperature of a capacitor of claim 42 wherein said circuit board comprises a material selected from the group consisting of alumina; aluminum nitride; silicon nitride and beryllium oxide.

44. The method for controlling a device temperature of a capacitor of claim 42 wherein said material is selected from the group consisting of FR 1, FR 2, FR 3, FR 4, FR 5, FR 6, CEM 1, CEM 2, CEM 3, CEM 4, CEM 5, 96% Al₂O₃ and 99.6% Al₂O₃.

45. The method for controlling a device temperature of a capacitor of claim 39 wherein said electronic component is between said circuit board and said thermoelectric cooler.

46. The method for controlling a device temperature of a capacitor of claim 39 wherein said thermoelectric cooler is between said circuit board and said electronic component.

47. The method for controlling a device temperature of a capacitor of claim 26 wherein said electronic module further comprises an overmolding over at least a portion of said electronic module.

48. The method for controlling a device temperature of a capacitor of claim 26 wherein said electronic module further comprises a heat sink in thermal contact with said thermoelectric cooler.

49. The method for controlling a device temperature of a capacitor of claim 48 wherein said heat sink is in thermal contact with said thermoelectric cooler opposite said electronic component.
